(19) United States
(12) Patent Application Publication
(10) Pub. No.: US 2024/0206153 A1
(43) Pub. Date: Jun. 20, 2024

(54) SEMICONDUCTOR DEVICE AND METHOD OF FABRICATING THE SAME

(71) Applicant: Fujian Jinhua Integrated Circuit Co., Ltd., Quanzhou City (CN)

(72) Inventors: Shuxian Wu, Quanzhou City (CN); Huihuang Tang, Quanzhou City (CN)

(73) Assignee: Fujian Jinhua Integrated Circuit Co., Ltd., Quanzhou City (CN)

(21) Appl. No.: 18/122,096

(22) Filed: Mar. 15, 2023

(30) Foreign Application Priority Data
Dec. 19, 2022 (CN) 202211634940.7
Dec. 19, 2022 (CN) 202223406358.3

(51) Int. Cl. H10B 12/00

(52) U.S. Cl. CPC H10B 12/315; H01L 28/92; H10B 12/03

(57) ABSTRACT

The invention discloses a semiconductor device and a method of fabricating the same. The semiconductor device includes a substrate, storage node pads, a capacitor structure and a supporting structure. The storage node pads are disposed on the substrate. The capacitor structure is disposed on the storage node pads and includes a plurality of capacitors. The capacitor structure includes a bottom electrode layer, a capacitor dielectric layer and a top electrode layer from bottom to top, wherein the top portion of the bottom electrode layer is provided with a recess. The supporting structure includes a plurality of first supporting layers and a plurality of second supporting layers from bottom to top, and the supporting structure connects two adjacent capacitors, wherein the recesses face each second supporting layer respectively.

### BACKGROUND OF THE INVENTION

### 1. Field of the Invention

The present invention relates to a semiconductor device and the method for fabricating the same, in particular to a semiconductor memory device and a method for fabricating the same.

### 2. Description of the Prior Art

With the trend of miniaturization of various electronic products, the design of semiconductor memory devices must meet the requirements of high integration and high density. For a dynamic random access memory (DRAM) having recessed gate structures, because the carrier channel of which is relatively long in the same semiconductor substrate compared with that of the DRAM without recessed gate structures, the leakage current from the capacitor structure in the DRAM can be reduced. Therefore, the DRAM having recessed gate structures has gradually replaced DRAM only having planar gate structures under the current mainstream development trend.

Generally, the DRAM having recessed gate structures is constructed by a large number of memory cells which are arranged to form an array area, and each of the memory cells can be used to store information. Each memory cell may include a transistor element and a capacitor element connected in series, which is configured to receive voltage information from word lines (WL) and bit lines (BL). In order to satisfy the requirements of advanced products, the density of memory cells in the array area must be further increased, which increases the difficulty and complexity of related fabricating processes and designs. Therefore, the present technology needs further improvement to effectively improve the efficiency and reliability of related memory devices.

### SUMMARY OF THE INVENTION

In order to achieve the above object, an embodiment of the present invention provides a semiconductor device, where at least a portion of a bottom electrode layer is additionally provided with a recess thereon facing a second supporting layer, so as to additionally widen the distance between the bottom electrode layers, which is beneficial to forming a capacitor dielectric layer and a top electrode layer with optimized structures. Therefore, the semiconductor device may improve the structural reliability of the storage node, and further optimize the function and efficiency thereof.

To achieve the above object, one embodiment of the present invention provides a method of fabricating a semiconductor device, which locally reduces the thickness of the top of a bottom electrode layer by lateral etching the bottom electrode layer in the etching process, so as to additionally form a recess facing a second supporting layer on the bottom electrode layer, thus optimizing the subsequent manufacturing process of a capacitor dielectric layer and a top electrode layer. Therefore, the method of fabricating a semiconductor device of the present invention may form a storage node with both structural reliability and device efficiency even on the premise of continuously increasing the storage cell density.

According to an embodiment of the present invention, a semiconductor device includes a substrate, a storage node pad, a capacitor structure, and a supporting structure. The storage node pad is disposed on the substrate. The capacitor structure is disposed on the storage node pad and includes a plurality of capacitors, each of the capacitors includes a bottom electrode layer, a capacitor dielectric layer and a top electrode layer from bottom to top, and the top portion of the bottom electrode layer is provided with a recess. The supporting structure includes a plurality of first supporting layers and a plurality of second supporting layers from bottom to top and the supporting structure connects two adjacent capacitors, wherein the recesses face each second supporting layer respectively.

According to an embodiment of the present invention, a method of fabricating a semiconductor device includes the following steps. First, a substrate is provided, and a plurality of storage node pads are formed on the substrate. Then, forming a capacitor structure on the storage node pads, wherein the capacitor structure includes a plurality of capacitors, and each of the capacitors includes a bottom electrode layer, a capacitor dielectric layer and a top electrode layer from bottom to top, and the top portion of the bottom electrode layer is provided with a recess. Then, a supporting structure is formed to connect two adjacent capacitors, and the supporting structure includes a first supporting layer and a second supporting layer from bottom to top, wherein the recesses face each second supporting layer respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

FIG. 1 to FIG. 7 are schematic diagrams illustrating a fabricating method of a semiconductor device according to a first embodiment in the present invention, wherein:

FIG. 1 shows a schematic cross-sectional view of a semiconductor device of the present invention after forming a supporting layer structure;

FIG. 2 shows a schematic cross-sectional view of a semiconductor device of the present invention after forming an electrode material layer;

FIG. 3 shows a schematic cross-sectional view of a semiconductor device of the present invention after a first etching process;

FIG. 4 shows a schematic cross-sectional view of a semiconductor device of the present invention after forming bottom electrode layers;

FIG. 5 shows a schematic cross-sectional view of a semiconductor device of the present invention after etching the supporting layer structure;

FIG. 6 shows a schematic cross-sectional view of a semiconductor device of the present invention after completely removing first supporting material layers and third supporting material layers; and

FIG. 7 shows a schematic cross-sectional view of a semiconductor device of the present invention after forming capacitors.

FIG. 8 to FIG. 9 are schematic diagrams illustrating a fabricating method of a semiconductor device according to a second embodiment in the present invention, wherein:

FIG. 8 shows a schematic cross-sectional view of a semiconductor device of the present invention after forming bottom electrode layers; and

FIG. 9 shows a schematic cross-sectional view of a semiconductor device of the present invention after forming capacitors.

FIG. 10 to FIG. 11 are schematic diagrams illustrating a fabricating method of a semiconductor device according to a third embodiment in the present invention, wherein:

FIG. 10 shows a schematic cross-sectional view of semiconductor device of the present invention after completely removing first supporting material layers and third supporting material layers; and

FIG. 11 shows a schematic cross-sectional view of semiconductor device of the present invention after forming capacitors.

FIG. 12 is a schematic diagram illustrating a fabricating method of a semiconductor device according to a fourth embodiment in the present invention.

### DETAILED DESCRIPTION

To provide a better understanding of the presented disclosure, preferred embodiments will be described in detail. The preferred embodiments of the present disclosure are illustrated in the accompanying drawings with numbered elements. In addition, the technical features in different embodiments described in the following may be replaced, recombined, or mixed with one another to constitute another embodiment without departing from the spirit of the present disclosure.

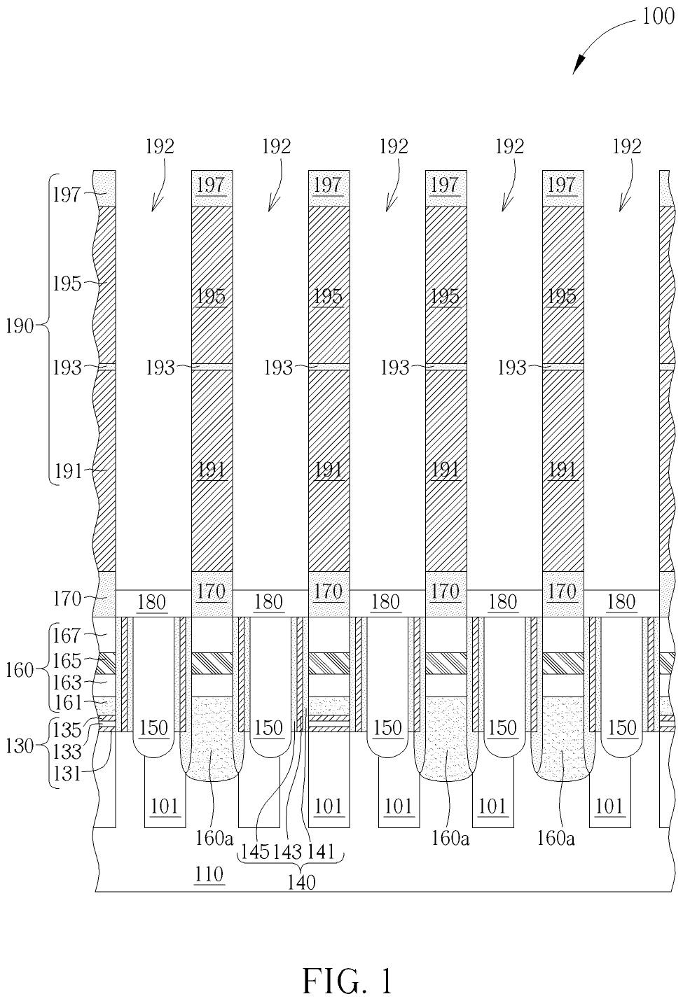

Referring to FIG. 1 to FIG. 7 which illustrate steps of a method for manufacturing a semiconductor device 100 in the first embodiment of the present invention. First, as shown in FIG. 1, a substrate 110 is provided, such as a silicon substrate, a silicon-containing substrate (such as SiC, SiGe, etc.) or a silicon-on-insulator (SOI) substrate. At least one insulating region 101, such as a shallow trench isolation (STI), is formed in the substrate 110, and multiple active areas (AA, not shown in the drawings) are defined on the substrate 110. In one embodiment, the insulating region 101 is formed by, for example, forming a plurality of trenches (not shown) in the substrate 110 by an etching process, and then filling the trenches with an insulating material (such as silicon oxide or silicon oxynitride), but not limited thereto.

In addition, a plurality of buried gates (not shown in the drawings) are further formed in the substrate 110. For example, the buried gates extend parallel to each other in one direction (e.g., an X direction, not shown in the drawings) and intersect with the active areas, so as to serve as buried word lines (BWL, not shown in the drawings) of the semiconductor device 100. A plurality of bit lines 160 and a plurality of contacts 150 may be formed on the substrate 110, wherein each of the bit lines 160 extends in another direction (e.g., a Y direction, not shown) perpendicular to the direction (e.g., the X direction, not shown in the drawings), so that, each bit lines 160 is alternately disposed with each contact 150 in the direction (e.g., the X direction, not shown in the drawings). Although the overall extension directions of the active areas, the buried gates and the bit lines 160 are not specifically depicted in the drawings of this embodiment, it should be easily understood by those skilled in the art that the bit line 160 should be perpendicular to the buried gate and intersected with the active areas and the buried gates in a plan view.

In detail, the bit lines 160 are formed on the substrate 110 and separated from each other, and each includes a semiconductor layer (e.g., including polysilicon) 161, a barrier layer 163 (e.g., including titanium and/or titanium nitride), a conductive layer 165 (e.g., low-resistance metal including tungsten, aluminum or copper), and a capping layer 167 (e.g., including silicon oxide, silicon nitride or silicon oxynitride) stacked in sequence, but not limited thereto. It should be noted that, in principle, all bit lines 160 are parallel to each other on the dielectric layer 130 which is on the substrate 110, where the dielectric layer 130 preferably includes a composite-layer structure, such as an oxide-nitride-oxide (ONO) structure including an oxide layer 131-a nitride layer 133-an oxide layer 135, but not limited thereto. In addition, each of the bit lines 160 extends across the active areas, where the bit line 160 across each active area may be further extended into each active area by a bit line contact (BLC) 160a correspondingly formed below the bit line 160.

It should be noted that the bit line contact 160a is integrally formed with the semiconductor layer 161 of the bit line 160 and directly contacts the underlying substrate 110 (i.e., the active area). On the other hand, each of the contacts 150 is also formed on the substrate 110 and separated from each other, and further extend into the active area, such that the contact 150 may be used as a storage node contact (SNC) of the semiconductor device 100, and directly contact the underlying substrate 110 (including the active area and the insulating region 101). In an embodiment, the contact 150 includes a low-resistance metal material, such as aluminum (Al), titanium (Ti), copper (Cu) or tungsten (W), and the contacts 150 and the bit lines 160 are insulated from each other by spacer structures 140. In an embodiment, the spacer structure 140 may optionally include a single layer structure or a composite-layer structure as shown in FIG. 1, which includes, but not limited to, a first spacer 141 (e.g., including silicon nitride), a second spacer 143 (e.g., including silicon oxide) and a third spacer 145 (e.g., including silicon nitride) stacked in sequence on the sidewalls of each bit line 160.

Referring to FIG. 1, a plurality of storage node pads (SN pad) 180 are also formed in a dielectric layer 170 which is on the substrate 110. The storage node pads 180 are located above the contacts 150 and the bit lines 160, and respectively align with the contacts 150. In an embodiment, the storage node pad 180 also includes a low-resistance metal material, such as aluminum, titanium, copper or tungsten, or such as a metal material different from the material of the contact 150, but not limited thereto. In another embodiment, the storage node pad 180 may be integrally formed with the contact 150 and may include the same material. Afterwards, a capacitor structure 250 may be subsequently formed above the storage node pad 180 to directly contact the storage node pad 180 below and to electrically connect to the storage node pad 180 below.

In an embodiment, the manufacturing process of the capacitor structure 250 includes the following steps, but not limited thereto. First, a supporting layer structure 190 is formed on a dielectric layer 170 which is on the substrate 110. For example, the supporting layer structure 190 includes at least one oxide layer and at least one nitride layer alternately stacked. In this embodiment, the supporting layer structure 190 includes, for example, a first supporting material layer 191 (e.g., including silicon oxide), a second supporting material layer 193 (e.g., including silicon nitride or silicon carbonitride), a third supporting material layer 195 (e.g., including silicon oxide), and a fourth supporting material layer 197 (e.g., including silicon nitride or silicon carbonitride) stacked in order from bottom to top, but not limited thereto. Preferably, the oxide layer (e.g., including the first supporting material layer 191 and the third supporting material layer 195) may have a relatively large thickness, for example, about 5 times to more than 10 times the thickness of the nitride layer (e.g., including the second supporting material layer 193 or the fourth supporting material layer 197), and the thickness of the nitride layer (e.g., including the fourth supporting material layer 197) located away from the substrate 110 is preferably greater than the thickness of the nitride layer (e.g., including the second supporting material layer) located close to the substrate 110, as shown in FIG. 1, but not limited thereto. Therefore, the overall thickness of the supporting layer structure 190 may reach about 1600 Å to about 2000 Å, but not limited thereto.

It should be understood by those skilled in the art that the specific stacking numbers of the aforementioned oxide layers (such as the first supporting material layer 191 or the third supporting material layer 195) and the aforementioned nitride layers (such as the second supporting material layer 193 or the fourth supporting material layer 197) are not limited to the aforementioned numbers, but may be adjusted according to the actual requirements (e.g., 3 layers, 4 layers or other numbers of layers). Then, a plurality of through holes 192 are formed in the supporting layer structure 190, which sequentially penetrate through the fourth supporting material layer 197, the third supporting material layer 195, the second supporting material layer 193 and the first supporting material layer 191, and align with the storage node pads 180 respectively. In this way, the top surface of each storage node pad 180 may be exposed from each of the through holes 192 as shown in FIG. 1.

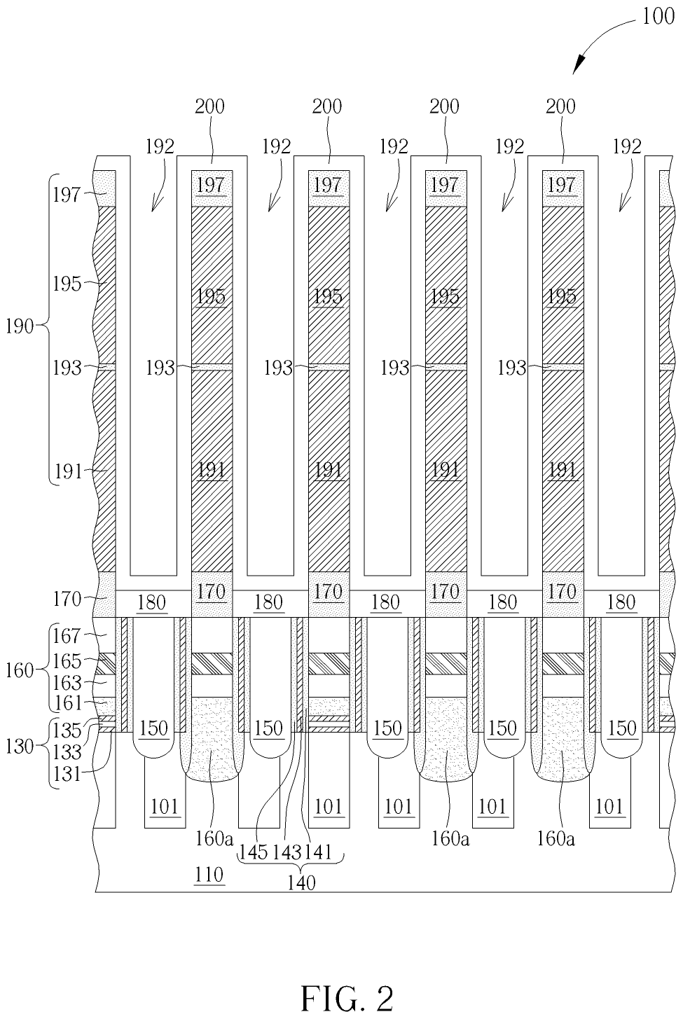

Then, as shown in FIG. 2, a deposition process is performed on the substrate 110 to form an electrode material layer 200. In detail, for example, the electrode material layer 200 is conformally formed on the supporting layer structure 190, which covers the top surface of the fourth supporting material layer 197, the surface of each through hole 192 and the top surface of each storage node pad 180. The electrode material layer 200 includes, but is not limited to, a low-resistance metal material, such as aluminum, titanium, copper or tungsten.

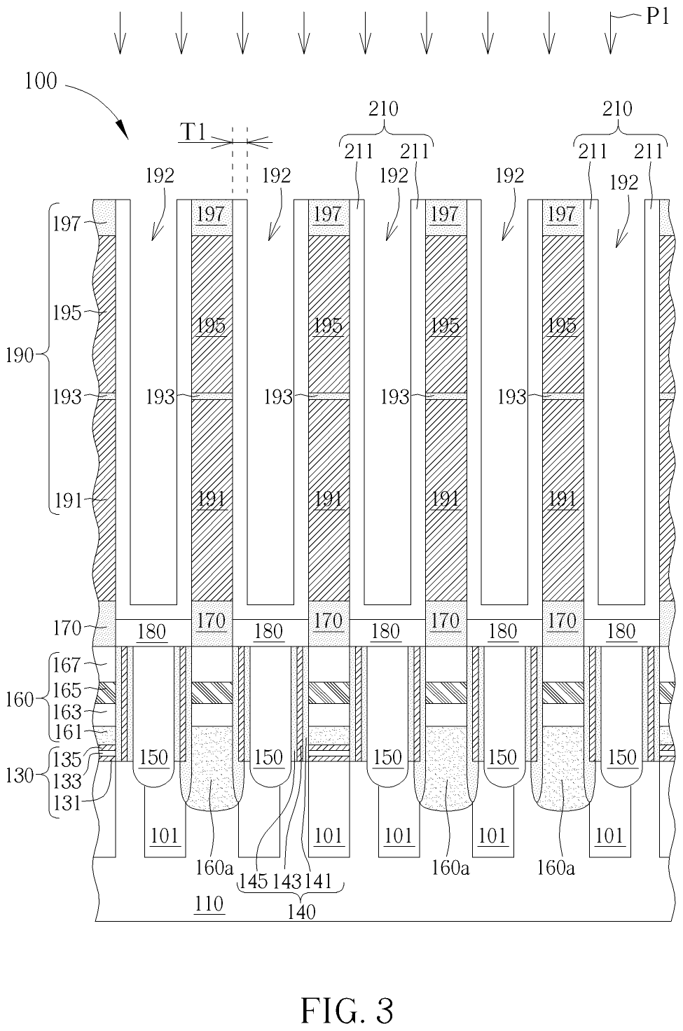

Then, as shown in FIG. 3, a first etching process P1, such as a dry etching process, is performed to remove the electrode material layer 200 covering the top surface of the fourth supporting material layer 197, and to form a plurality of initial bottom electrode layers 210. Each of the initial bottom electrode layers 210 is formed in each through hole 192, and uniformly covers the top surface of each storage node pad 180 and the surface of each through hole 192, and may have a uniform first thickness T1 as a whole. In addition, each of the initial bottom electrode layers 210 covers two opposite sidewalls of each through hole 192 at the same time, so it may have two first portions 211 with the same height extending upward in the direction perpendicular to the substrate 110. The top surface of each first portion 211 is, for example, coplanar with the top surface of the fourth supporting material layer 197. In this way, each of the initial bottom electrode layers 210 may have a bilaterally symmetrical structure, such as a U-shaped structure as shown in FIG. 3, but not limited thereto.

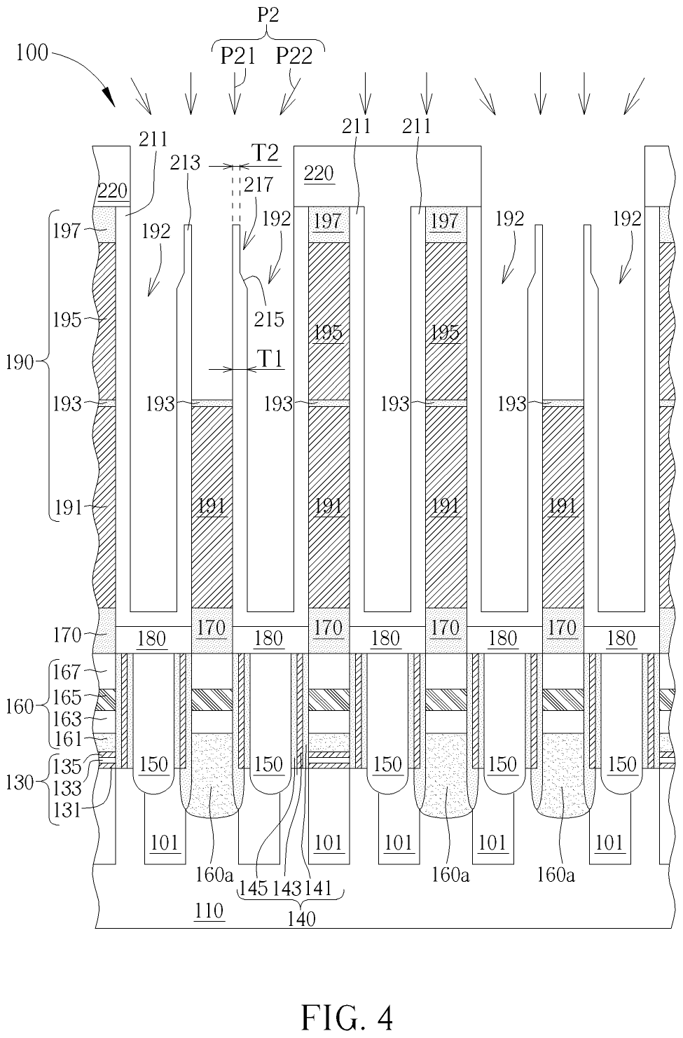

As shown in FIG. 4, a plurality of mask patterns 220 are formed on the supporting layer structure 190, which covers a portion of the fourth supporting material layer 197 and a portion of the through holes 192, and a second etching process P2, such as another dry etching process, is performed through the mask patterns 220. In detail, each of the mask patterns 220 is sequentially formed on the supporting layer structure 190 in such a way that simultaneously cover one specific through hole 192 and the supporting layer structure 190 on both sides of the specific through hole 192, and expose two through holes 192 adjacent to the left and right sides of the specific through hole 192, so that the remaining portion of the fourth supporting material layer 197 may be exposed from the mask patterns 220. Then, the remaining portion of the fourth supporting material layer 197 is removed by a vertical downward etching process P21 in the second etching process P2 to expose the underlying third supporting material layer 195. On the other hand, when the remaining portion of the fourth supporting material layer 197 is removed, the first portions 211 which are exposed from the mask patterns 220 may also be partially removed via the vertical downward etching process P21 and the lateral etching process P22 of the second etching process P2, with the vertical downward etching process P21 reducing the height of the exposed first portions 211, and with the lateral etching process P22 locally reducing the thickness of the exposed first portions 211. Accordingly, a second portion 213 with a lower height and a local thinner portion may be formed.

It should be noted that, in this embodiment, the parameters of the lateral etching process P22 (such as etching temperature, etching rate, or etching selectivity ratio, etc.) are further adjusted, so as to deliberately form a uniform and relatively small second thickness T2 on the top of the second portion 213. Meanwhile, according to the etching angle of the lateral etching process P22, an inclined surface 215 which gradually inclines downward and faces the unetched fourth supporting material layer 197 is formed on the second portion 213. Therefore, a recess 217 facing the fourth supporting material layer 197 is disposed on each second portion 213 as shown in FIG. 4. In this way, the top diameter of each through hole 192 exposed from the mask patterns 220 may be correspondingly enlarged. Furthermore, it should be noted that, in the direction perpendicular to the substrate 110, the inclined surface 215 on the second portion 213 is located between the unetched fourth supporting material layer 197 and the unetched second supporting material layer 193, such that the second portion 213 may therefore obtain a relatively small second thickness T2 above the inclined surface 215, and a relatively large first thickness T1 below the inclined surface 215.

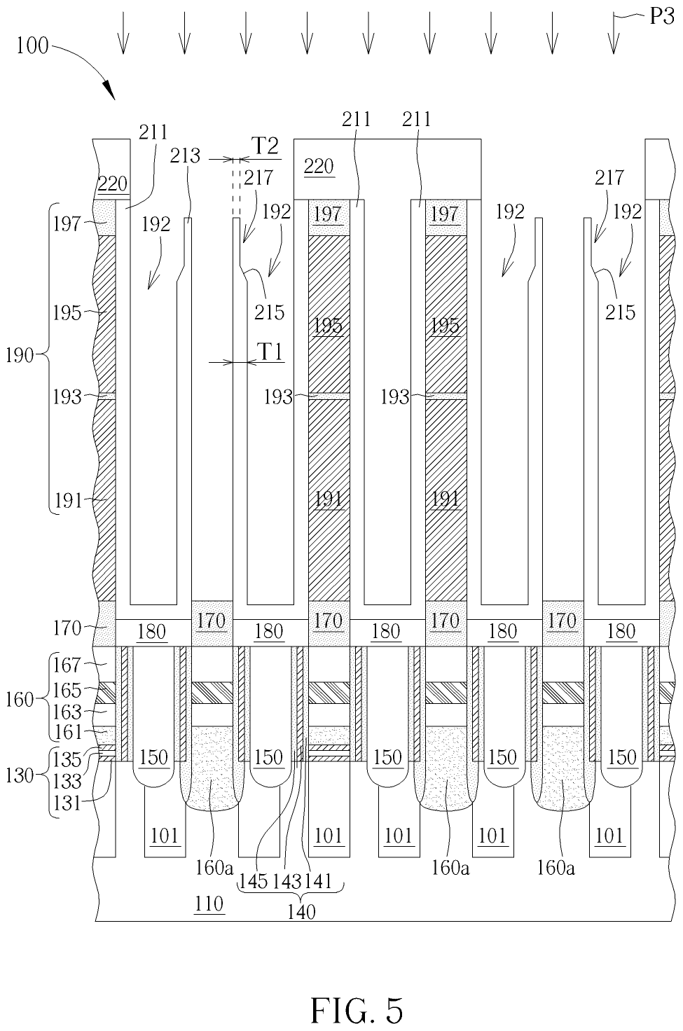

As shown in FIG. 5, a third etching process P3 is performed through the mask patterns 220, such as a dry etching process or a wet etching process having a higher etching selectivity, to completely remove the exposed third supporting material layer 195 exposed from the mask patterns 220, and the second supporting material layer 193 and the first supporting material layer 191 underneath. In other words, the third etching process P3 removes the supporting layer structure 190 directly contacting each second portion 213, but keeps the supporting layer structure 190 directly contacting each first portion 211. Then, the mask patterns 220 is completely removes.

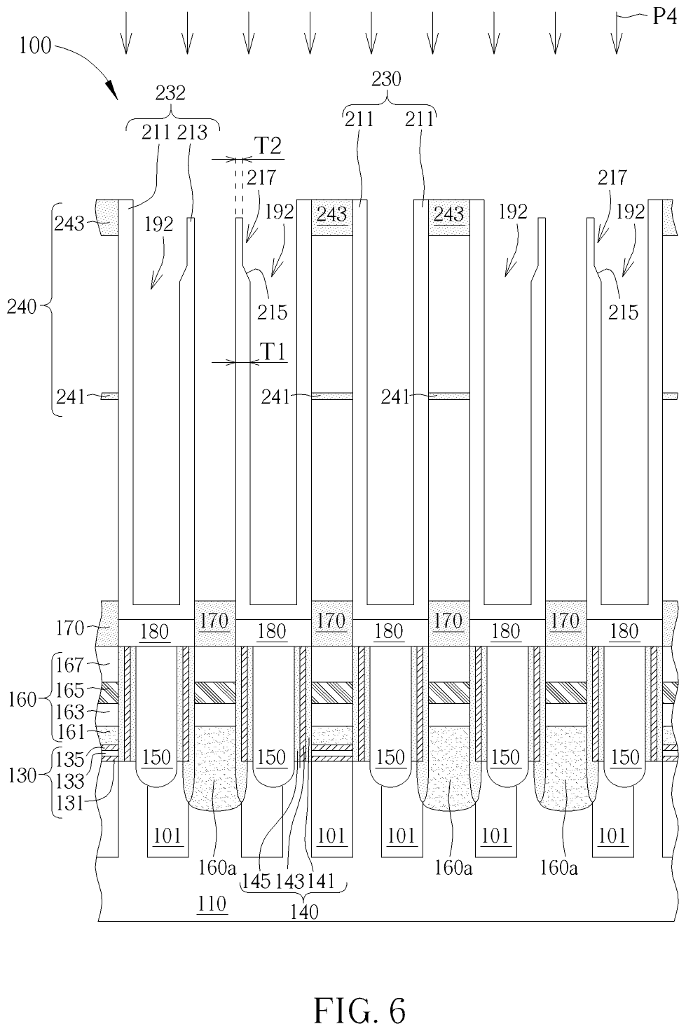

Then, as shown in FIG. 6, a fourth etching process P4, such as an isotropic wet etching process, is performed to completely remove the remaining third supporting material layer 195 and the first supporting material layer 191. In detail, in the isotropic wet etching process, an etchant such as tetramethylammonium hydroxide (TMAH) is introduced, and the etchant continuously removes the remaining third supporting material layer 195 and the remaining first supporting material layer 191 through both sides of the space which is generated due to the removal of the supporting layer structure 190 in the third etching process P3, but the etchant is not limited thereto. In this way, a plurality of bottom electrode layers 230, 232 may be formed, where each of the bottom electrode layers 230 has two first portions 211 extending upward and having the same height in the direction perpendicular to the substrate 110 to present a symmetrical U-shaped structure, while the bottom electrode layer 232 has a first portion 211 and a second portion 213 oppositely disposed to each other in the direction perpendicular to the substrate 110 to present an asymmetrical U-shaped structure.

Meanwhile, the remaining second supporting material layer 193 and the remaining fourth supporting material layer 197 may form a first supporting layer 241 and a second supporting layer 243, respectively, and the first supporting layer 241 and the second supporting layer 243 sequentially disposed from bottom to top may jointly form a supporting structure supporting the bottom electrode layers 230 and 232, and directly contact and support the first portion 211 of each bottom electrode layer 230 and 232. The top surface of the second supporting layer 243 may be flush with the top surface of the first portion 211 of each bottom electrode layer 230, 232 and be higher than the top surface of the second portion 213, and the thickness of the second supporting layer 243 may be preferably larger than the thickness of the first supporting layer 241 disposed adjacent to the substrate 110 (e.g., about 2 to 5 times the thickness of the first supporting layer 241, as shown in FIG. 6), but not limited thereto.

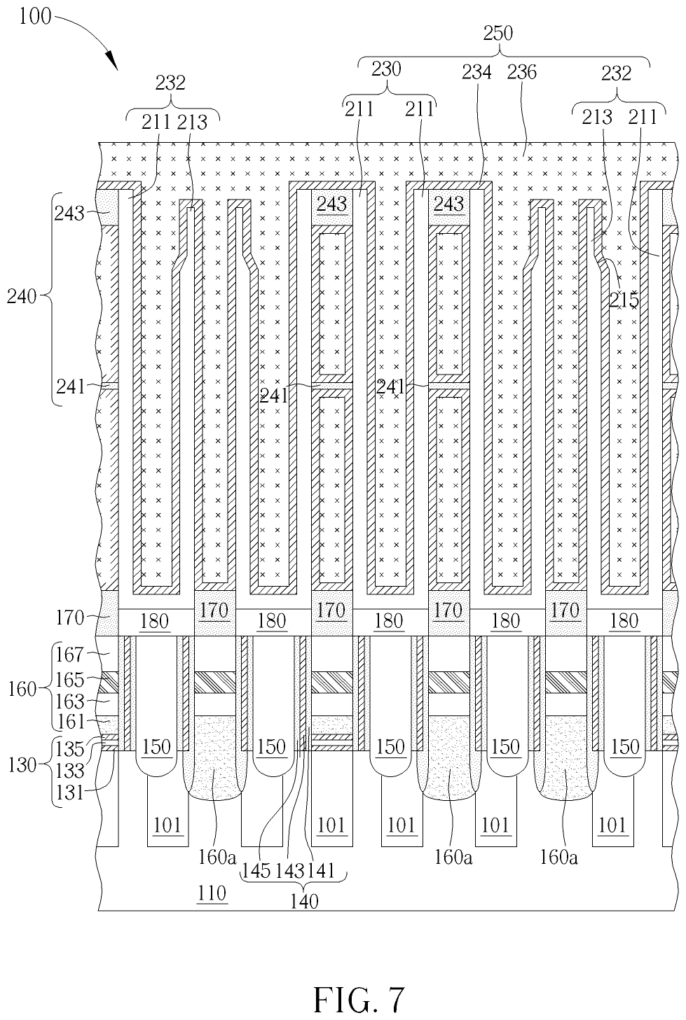

Then, as shown in FIG. 7, a deposition process is performed on the substrate 110 to sequentially form a capacitor dielectric layer 234 and a top electrode layer 236, such that the bottom electrode layers 230 and 232, the capacitor dielectric layer 234 and the top electrode layer 236 may jointly form the capacitor structure 250. In detail, the capacitor dielectric layer 234 conformally covers the exposed surfaces of the bottom electrode layers 230, 232 and the dielectric layer 170, while the top electrode layer 236 fills up the remaining space between the bottom electrode layers 230, 232. Portions of the capacitor dielectric layer 234 and the top electrode layer 236 may be further filled between the second supporting layer 243 and the first supporting layer 241, as well as between the first supporting layer 241 and the dielectric layer 140. In an embodiment, the capacitor dielectric layer 234 includes, for example, a dielectric material with a high dielectric constant, such as hafnium oxide (HfO₂), hafnium silicon oxide (HfSiO₄), hafnium silicon oxynitride (HfSiON), zinc oxide (ZrO₂), titanium oxide (TiO₂) and zirconia-alumina-zirconia (ZAZ), preferably including zirconia-alumina-zirconia. The top electrode layer 236 includes, for example, a low-resistance metal material, such as aluminum, titanium, copper or tungsten, preferably including titanium, but not limited thereto.

In this way, the manufacturing process of the capacitor structure 250 is completed. The capacitor structure 250 includes a plurality of vertically extending capacitors to serve as storage nodes (SN) of the semiconductor device 100. The storage nodes may be electrically connected to transistor components (not shown in the drawings) of the semiconductor device 100 through the storage node pads 180 and the storage node plugs (i.e., contacts 150), such that the capacitor structure 250 may have a good contact relationship with the storage node plugs disposed on the substrate 110. Therefore, the semiconductor device 100 of this embodiment may form a dynamic random access memory (DRAM) device, where at least one transistor component and at least one capacitor form a smallest memory cell in the DRAM array to receive voltage information from the bit line 160 and the buried word line.

According to the manufacturing method in the first embodiment of the present invention, when the fourth supporting material layer 197 of the semiconductor device 100 is partially removed, the first portion of the initial bottom electrode layer 210 is simultaneously etched through a vertically downward etching process P21 of the etching process (the second etching process P2 shown in FIG. 4), so as to reduce the height of a portion of the first portion 211. At the same time, the thickness of the first portion 211 is locally reduced through the lateral etching process P22 of the etching process to from the second portion 213 with a lower height and a local thinner portion. In this way, at least a portion of the bottom electrode layer 232 is consist of the first portion 211 and the second portion 213 with different heights, and thus presents an asymmetric U-shaped structure. In addition, in particular, the top portion of the second portion 213 has a recess 217 with its opening facing the second supporting layer 243, such that the top diameter of each through hole 192 may be correspondingly enlarged to additionally widen the distance between the first portion 211 and the second portion 213 of each of the bottom electrode layers 230, 232 (as shown in FIG. 4). Under this operation, the subsequent deposition processes for forming the capacitor dielectric layer 234 and the top electrode layer 236 may be carried out more smoothly, such that the capacitor dielectric layer 234 may uniformly and conformally cover the bottom electrode layers 230 and 232, and the top electrode layer 236 may be densely filled into the remaining space to thereby form the semiconductor device 100 with an optimized structure. Therefore, the method of manufacturing the semiconductor device 100 in the first embodiment of the present invention may effectively ameliorate the manufacturing defects caused by the increase in memory cell density, optimize the manufacturing processes of the capacitor dielectric layer 234 and the top electrode layer 236, and further achieve the effect of improving the functional and structural reliability of the semiconductor device 100.

In addition, it should be easily understood by those skilled in the art that, in order to meet the actual product requirements, the semiconductor device and the manufacturing method thereof of the present invention may have other embodiments, but not limited to the foregoing. For example, when the supporting layer structure 190 is partially removed through the mask patterns 220, the second etching process may be used to remove the remaining fourth supporting material layer 197 and the third supporting material layer 195 below it, thus exposing the second supporting material layer 193. Then the third supporting material layer 195 is completely removed by an isotropic wet etching process. Afterwards, the exposed second supporting material layer 193 and the first supporting material layer 191 below it are removed through the mask patterns 220 by a subsequent etching process. The remaining first supporting material layer 191 is completely removed by another isotropic wet etching process. Other embodiments or variations of the manufacturing method of the semiconductor device in the present invention are further described below. In order to simplify the explanation, the following description mainly focuses on the differences of each embodiment, and the similarities are not repeated. In addition, the same components in each embodiment of the present invention are labeled with the same reference numerals, so as to facilitate the cross-reference among the embodiments.

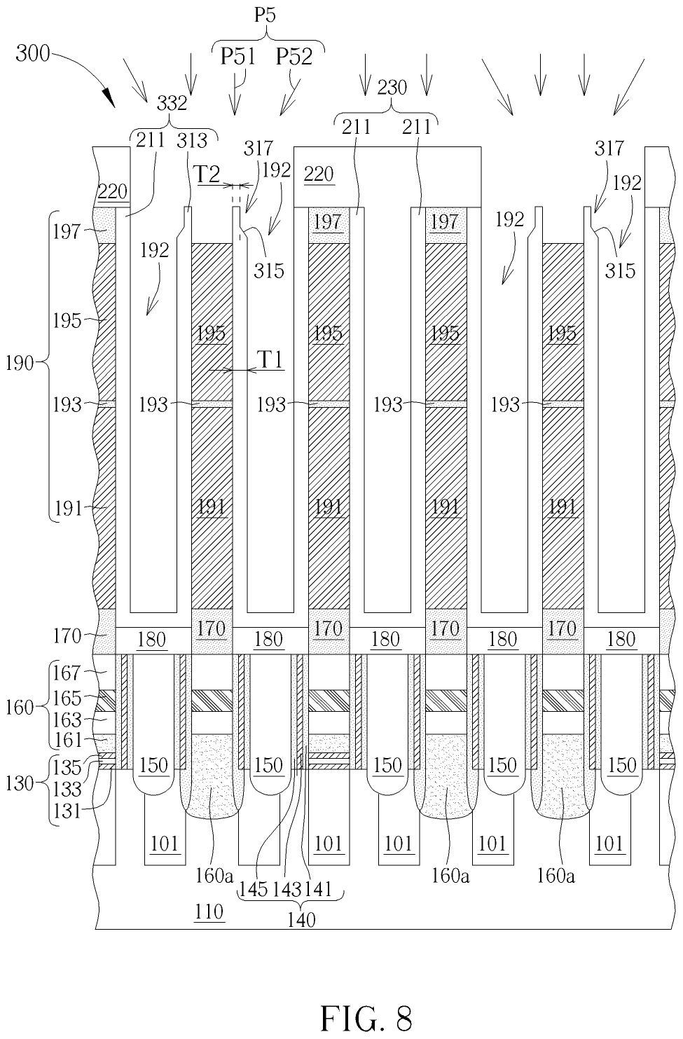

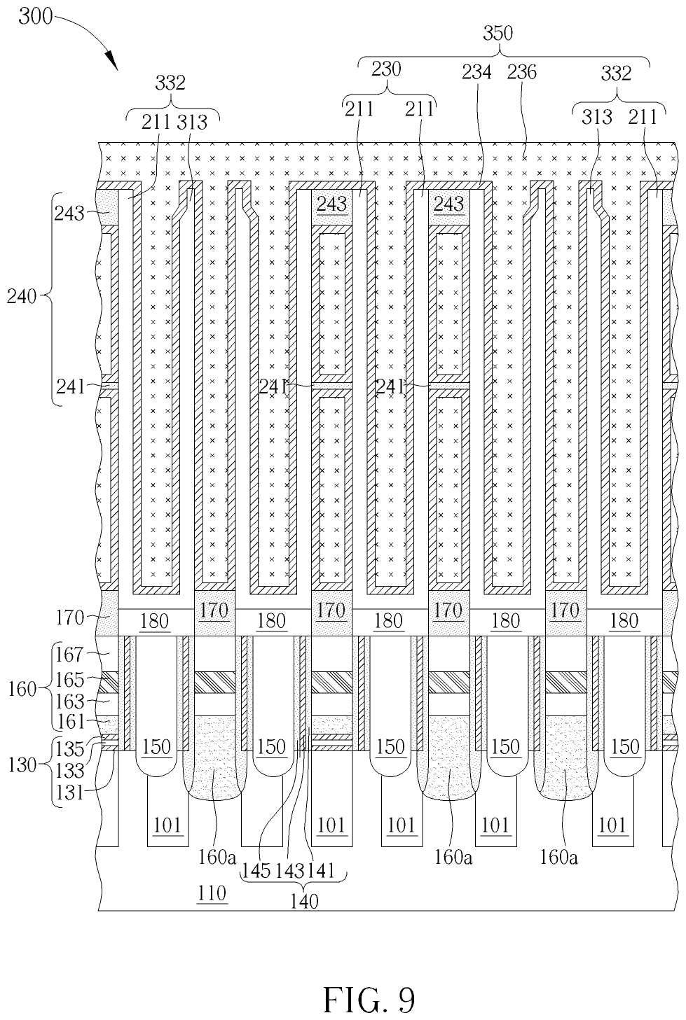

Referring to FIG. 8 to FIG. 9 which illustrate the steps of the method of manufacturing a semiconductor device 300 in the second embodiment of the present invention. The manufacturing steps of the semiconductor device 300 in this embodiment are basically the same as those of the semiconductor device 100 in the first embodiment, and are not be repeated here. The main difference between this embodiment and the aforementioned first embodiment is that, in this embodiment, by adjusting various parameters of a second etching process P5, a vertical downward etching process P51 does not affect the height of the first portion 211, and only a lateral etching process P52 locally reduces the thickness of the exposed first portion 211, so as to form a locally thinner second portion 313 with the same height as that of the first portion 211.

It should be noted that the second portion 313 is also partially formed with a second thickness T2 which is uniform and relatively small, and an inclined surface 315 which gradually inclines downward and faces the unetched fourth supporting material layer 197, such that a recess 317 facing the fourth supporting material layer 197 may be formed at the top of the second portion 313 as shown in FIG. 8. Note that the inclined surface 315 on the second portion 313 is located between the top surface and the bottom surface of the unetched fourth supporting material layer 197 in the direction perpendicular to the substrate 110, such that the portion of the second portion 313 above the inclined surface 315 has a relatively small second thickness T2, while the portion of the second portion 313 below the inclined surface 315 has a relatively large first thickness T1. In this way, at least a portion of the bottom electrode layer 332 is consist of the first portion 211 and the second portion 313 which have the same height and flush top surfaces with the top surface of the fourth supporting material layer 197, where the second portion 313 is thinner locally, such that the bottom electrode layer 332 as a whole presents an asymmetric U-shaped structure. Under this operation, the top diameter of each through hole 192 exposed from the mask pattern 220 may also be correspondingly enlarged, which is beneficial to the subsequent deposition process.

Then, the third etching process P3 shown in FIG. 5, the fourth etching process P3 shown in FIG. 6, and the deposition process of the capacitor dielectric layer 234 and the top electrode layer 236 shown in FIG. 7 in the previous embodiment are subsequently performed to form the semiconductor device 300 shown in FIG. 9, such that the bottom electrode layers 230 and 332, the capacitor dielectric layer 234 and the top electrode layer 236 may jointly form the capacitor structure 350. In this embodiment, the fabrication and material selection of the capacitor dielectric layer 234 and the top electrode layer 236 are basically the same as those of the first embodiment, so they are not repeated here.

In this way, the semiconductor device 300 of this embodiment is completed. In the capacitor structure 350 of this embodiment, the bottom electrode layers 230, 332, the capacitor dielectric layer 234 and the top electrode layer 236 are stacked sequentially to form a plurality of vertically extending capacitors which serve as storage nodes of the semiconductor device 300, and are electrically connected to the transistor components (not shown) of the semiconductor device 300 through the storage node pads 180 and the storage node plugs (i.e., contacts 150). Therefore, the semiconductor device 300 of this embodiment may also form a dynamic random access memory device.

According to a method of manufacturing a semiconductor device in the second embodiment of the present invention, when the fourth supporting material layer 197 is partially removed, the thickness of the first portion 211 is partially reduced by a lateral etching process P52 in the etching process (the second etching process P5 shown in FIG. 8) to form a locally thinner second portion 313. In this way, at least a portion of the bottom electrode layer 332 includes the second portion 313 with the same height as the first portion 211, the top surface flush with the top surface of the second supporting layer 243, but the locally thinner thickness, and thus presents an asymmetric U-shaped structure as a whole. The inclined surface 315 of the second portion 313 is higher than the bottom surface of the second supporting layer 243 in the direction perpendicular to the substrate 110. Under this arrangement, the top portion of the second portion 313 also includes a recess 317 with its opening facing the second supporting layer 243, so as to additionally widen the distance between the first portion 211 and the second portion 313 of each of the bottom electrode layers 230, 332 (as shown in FIG. 8), which is beneficial to the subsequent deposition processes for forming the capacitor dielectric layer 234 and the top electrode layer 236. Therefore, the manufacturing method of the semiconductor device 300 in the second embodiment of the present invention may also effectively ameliorate the manufacturing defects caused by the increase of memory cell density, optimize the manufacturing processes of the capacitor dielectric layer 234 and the top electrode layer 236, and further achieve the effect of improving the functional and structural reliability of the semiconductor device 300.

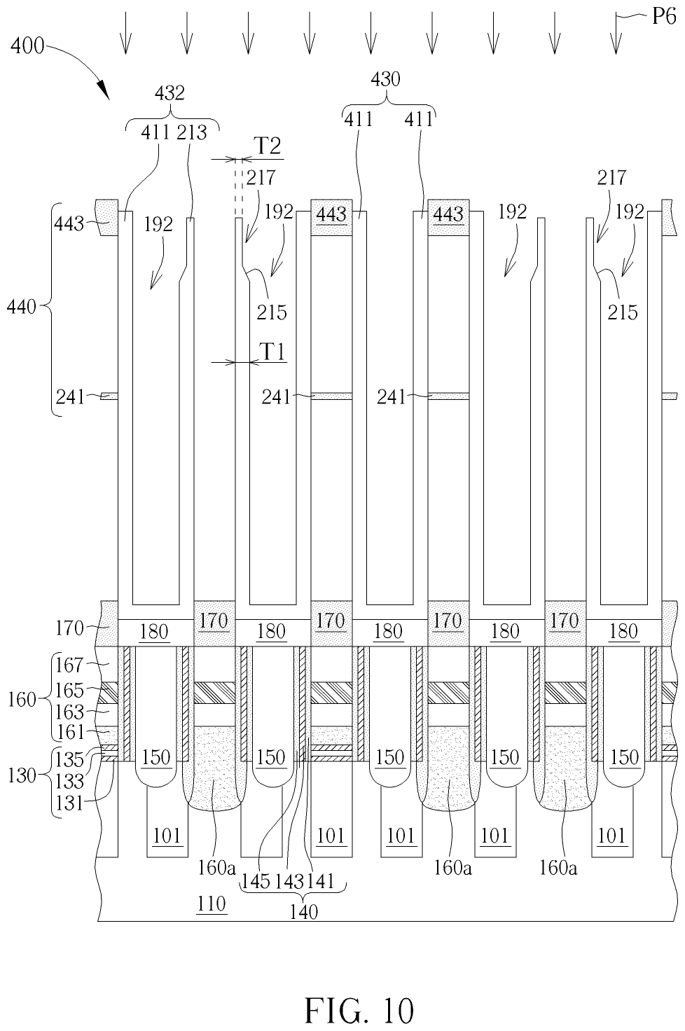

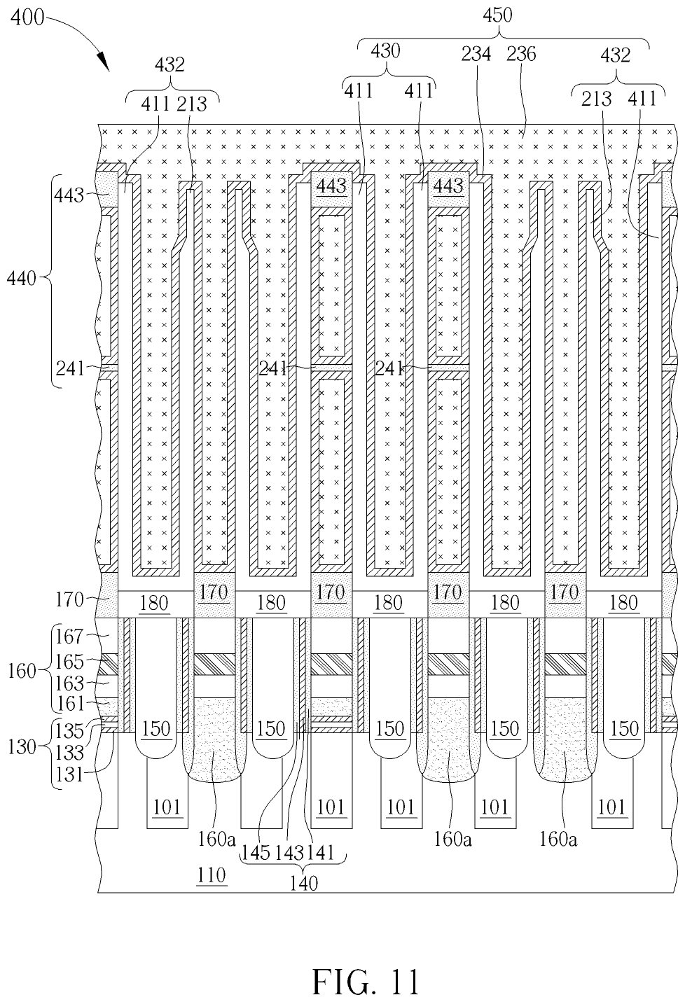

Referring to FIG. 10 to FIG. 11 which illustrate the steps of a method of fabricating a semiconductor device 400 in the third embodiment of the present invention. The steps of fabricating the semiconductor device 400 in this embodiment are basically the same as those of the semiconductor device 100 in the first embodiment, and are not repeated here. The main difference between this embodiment and the aforementioned first embodiment is that, in this embodiment, when the mask patterns 220 shown in FIG. 5 are removed, the remaining fourth supporting material layer 197 and the remaining first portion 211 shown in FIG. 5 are partially etched together.

In detail, in this embodiment, when the mask pattern 220 is removed, a first portion 411 with a lower height and a second supporting layer 443 with a thinner thickness are further formed, such that the height of the first portion 411 may be the same as the height of the second portion 213 and slightly lower than the top surface of the second supporting layer 443, and then a fourth etching process P6 is performed to completely remove the remaining third supporting material layer 195 and the first supporting material layer 191 as shown in FIG. 5. In this way, a portion of the bottom electrode layer 430 is consist of two first portions 411 with the same height and uniform first thickness T1, while the other portion of the bottom electrode layer 432 is consist of the first portion 411 and the second portion 213 both with the same height and the top surface lower than the top surface of the second supporting layer 443, wherein the second portion 213 is thinner locally, such that the bottom electrode layer 432 as a whole presents an asymmetric U-shaped structure. It is noted that, in this embodiment, the inclined surface 215 of the second portion 213 is still located between the second supporting layer 443 and the first supporting layer 241 in the direction perpendicular to the substrate 110, such that the portion of the second portion 213 above the inclined surface 215 has the relatively small second thickness T2, while the portion of the second portion 213 below the inclined surface 215 has the relatively large first thickness T1. In this operation, the top diameter of some through holes 192 may also be correspondingly enlarged, which is beneficial to the subsequent deposition process.

Then, as shown in FIG. 11, the deposition process is subsequently performed to form the capacitor dielectric layer 234 and the top electrode layer 236. In this way, the bottom electrode layers 430 and 432, the capacitor dielectric layer 234 and the top electrode layer 236 may jointly form a capacitor structure 450. In this embodiment, the fabrication and material selection of the capacitor dielectric layer 234 and the top electrode layer 236 are basically the same as those of the first embodiment, so they are not repeated here. In this way, the semiconductor device 400 of this embodiment completed. The capacitor structure 450 of this embodiment also includes a plurality of vertically extending capacitors which serve as storage nodes of the semiconductor device 400, and are electrically connected to transistor components (not shown) of the semiconductor device 400 through the storage node pads 180 and the storage node plugs (i.e., contacts 150). Therefore, the semiconductor device 400 of this embodiment may also form a dynamic random access memory device.

According to the manufacturing method in the third embodiment of the present invention, when the mask pattern 220 is removed, the remaining fourth support material layer 197 and the remaining first portion 211 of the semiconductor device 400 are partially etched in the etching process for removing the mask patterns 220. In this way, a portion of the bottom electrode layer 430 is consist of two first portions 411 with the same height and the top surfaces slightly lower than top surface of the second supporting layer 443, while another portion of the bottom electrode layer 432 is consist of the first portion 411 and the second portion 213 with the same height and the top surfaces lower than the top surface of the second supporting layer 443. Under this arrangement, the top portion of the second portion 213 also has a recess 217 with an opening facing the second supporting layer 443, so as to additionally widen the distance between the first portion 411 and the second portion 313 of each of the bottom electrode layers 430, 432 (as shown in FIG. 10), which is beneficial to the subsequent deposition processes for forming the capacitor dielectric layer 234 and the top electrode layer 236. Therefore, the manufacturing method of the semiconductor device 400 in the third embodiment of the present invention may also effectively ameliorate the manufacturing defects caused by the increase in memory cell density, optimize the manufacturing processes of the capacitor dielectric layer 234 and the top electrode layer 236, and further achieve the effect of improving the functional and structural reliability of the semiconductor device 400.

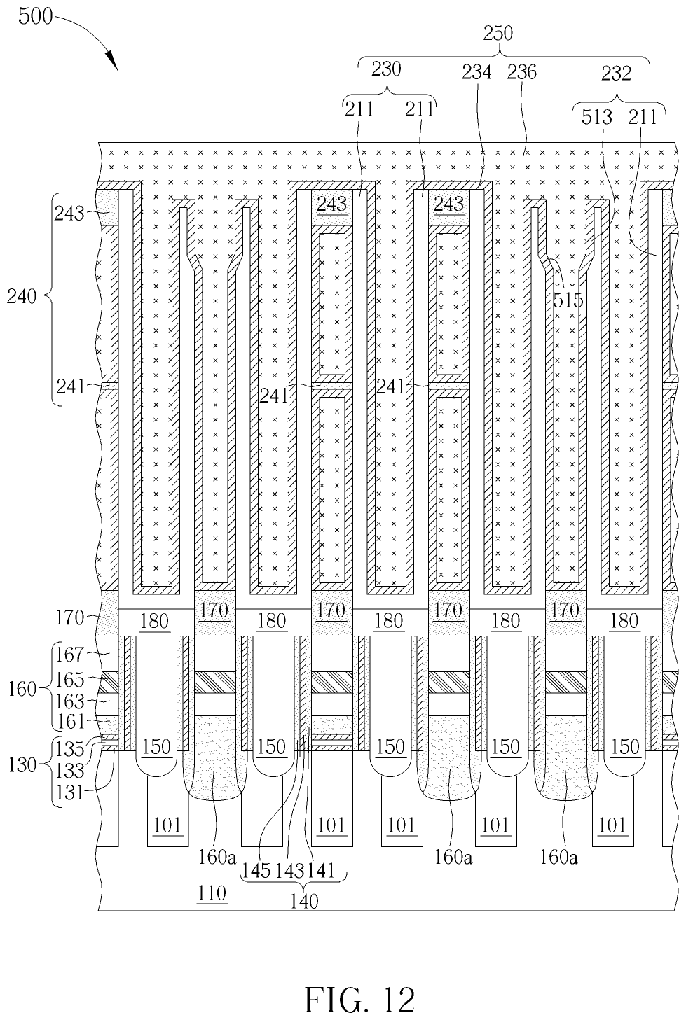

Referring to FIG. 12 which illustrates a method of fabricating a semiconductor device 500 in the fourth embodiment of the present invention. The steps of fabricating the semiconductor device 500 in this embodiment are basically the same as those of the semiconductor device 100 in the first embodiment, and are not repeated here. The main difference between this embodiment and the aforementioned first embodiment is that, in this embodiment, by adjusting various parameters of an etching process, an inclined surface 515 of the second portion 513 faces the adjacent inclined surface 515 of the second portion 513. In this way, the top space between two adjacent second portions 513 may be correspondingly enlarged, which is beneficial to the subsequent deposition processes for forming the capacitor dielectric layer 234 and the top electrode layer 236.

According to one of the embodiments of the present invention, a top surface of the second portion 513 may be flush with the top surface of the second supporting layer 243 depending on different parameters of an etching process, such that the inclined surface 515 is located between the bottom surface of the second supporting layer 243 and the first supporting layer 241 in the direction perpendicular to the substrate 110. However, in another embodiment, the top surface of the second portion 513 may also be not flush with the top surface of the second supporting layer 243 as shown in FIG. 12, for example being lower than the top surface of the second supporting layer 243, by modifying the parameters of an etching process based on practical requirements, but not limited thereto. Besides, in a further embodiment (not shown in the drawings), according to practical requirements, the top surface of the first portion 211 may be optionally flush with the top surface of the second portion 513 by modifying parameters of an etching process. The top surface of the second portion 513 may be optionally flush with the top surface of the second supporting layer 243 as shown in FIG. 9 or the top surface of the second portion 513 may be lower than the top surface of the second supporting layer 243 as shown in FIG. 11. The inclined surface 515 on the second portion 513 may be higher than the bottom surface of the second supporting layer 243, and the inclined surface 515 on the second portion 513 may be located between the bottom surface and the top surface of the second supporting layer 243 in the direction perpendicular to the substrate 110 as shown in FIG. 9, or the inclined surface 515 on the second portion 513 may be located between the bottom surface of the second supporting layer 243 and the first supporting layer 241.

Therefore, the manufacturing method of the semiconductor device 500 in the fourth embodiment of the present invention may also effectively ameliorate the manufacturing defects caused by the increase in memory cell density, optimize the manufacturing processes of the capacitor dielectric layer 234 and the top electrode layer 236, and further achieve the effect of improving the functional and structural reliability of the semiconductor device 500.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a plurality of storage node pads disposed on the substrate;
a capacitor structure disposed on the storage node pads, wherein the capacitor structure comprises a plurality of capacitors, each of the capacitors comprises a bottom electrode layer, a capacitor dielectric layer and a top electrode layer from bottom to top, and a top portion of the bottom electrode layer comprises a recess; and
a supporting structure comprising a plurality of first supporting layers and a plurality of second supporting layers from bottom to top, and the supporting structure connecting two adjacent capacitors, wherein each of the recesses faces each of the second supporting layers.

2. The semiconductor device according to claim 1, wherein the bottom electrode layer further comprises an inclined surface, the bottom electrode layer comprises a first thickness below the inclined surface and a second thickness above the inclined surface, and the first thickness is greater than the second thickness.

3. The semiconductor device according to claim 2, wherein the inclined surface is located between the second supporting layers and the first supporting layers in a direction perpendicular to the substrate.

4. The semiconductor device according to claim 2, wherein the inclined surface is higher than a bottom surface of the second supporting layers in the direction perpendicular to the substrate.

5. The semiconductor device according to claim 1, wherein the bottom electrode layer comprises a first portion and a second portion respectively extending upward, the recess is disposed on the second portion, and a top surface of the second portion is lower than a top surface of the second supporting layer.

6. The semiconductor device according to claim 5, wherein a top surface of the first portion is flush with the top surface of the second supporting layer.

7. The semiconductor device according to claim 5, wherein a top surface of the first portion is lower than the top surface of the second supporting layer.

8. The semiconductor device according to claim 5, wherein a top surface of the first portion or the top surface of the second portion is higher than a bottom surface of the second supporting layer.

9. The semiconductor device according to claim 5, wherein each of the first portions directly contacts each first supporting layer and each second supporting layer of the supporting structure.

10. The semiconductor device according to claim 1, wherein each of the bottom electrode layers comprises a symmetrical u-shaped structure or an asymmetrical u-shaped structure.

11. A method for manufacturing a semiconductor device, comprising:
providing a substrate;
forming a plurality of storage node pads on the substrate;
forming a capacitor structure on the storage node pads, wherein the capacitor structure comprises a plurality of capacitors, each of the capacitors comprises a bottom electrode layer, a capacitor dielectric layer and a top electrode layer from bottom to top, and a top portion of the bottom electrode layer comprises a recess; and
forming a supporting structure connecting two adjacent capacitors, wherein the supporting structure comprises a first supporting layer and a second supporting layer from bottom to top, and each of the recesses faces the second supporting layer.

12. The manufacturing method according to claim 11, wherein forming the supporting structure further comprises:
forming a first supporting material layer, a second supporting material layer, a third supporting material layer and a fourth supporting material layer stacked in sequence on the substrate;
forming a plurality of through holes penetrating through the fourth supporting material layer, the third supporting material layer, the second supporting material layer and the first supporting material layer;
forming a plurality of mask patterns on the fourth supporting material layer;
removing a portion of the fourth supporting material layer, a portion of the third supporting material layer, a portion of the second supporting material layer and a portion of the first supporting material layer through the mask patterns;
removing the mask patterns; and
completely removing the first supporting material layer to form the supporting structure.

13. The manufacturing method according to claim 12, further comprising:
forming an electrode material layer covering a surface of each through hole;
partially removing the electrode material layer to form a plurality of initial bottom electrode layers; and
performing an etching process to etch the initial bottom electrode layers through the mask patterns to thereby form the bottom electrode layer.

14. The manufacturing method according to claim 13, wherein the etching process comprises laterally etching the initial bottom electrode layers and vertically etching the initial bottom electrode layers to form the bottom electrode layers.

15. The manufacturing method according to claim 14, wherein each of the bottom electrode layers further comprises an inclined surface, each of the bottom electrode layers comprises a first thickness below the inclined surface and a second thickness above the inclined surface, and the first thickness is greater than the second thickness.

16. The manufacturing method according to claim 13, wherein the etching process is performed simultaneously with removing the portion of the fourth supporting material layer.

17. The manufacturing method according to claim 13, wherein after the etching process, removing the portion of the third supporting material layer, the portion of the second supporting material layer and the portion of the first supporting material layer.

18. The manufacturing method according to claim 13, wherein when removing the mask patterns, partially removing a remaining portion of the fourth supporting material layer.

19. The manufacturing method according to claim 18, wherein each of the bottom electrode layers comprises a first portion and a second portion respectively extending upward, and the recess is formed on the second portion, wherein a top surface of the first portion is lower than a top surface of the second supporting layer after partially removing the remaining portion of the fourth supporting material layer.

20. The manufacturing method according to claim 18, wherein the bottom electrode layer comprises a first portion and a second portion respectively extending upward, and the recess is formed on the second portion, wherein a top surface of the first portion is flush with a top surface of the second supporting layer after partially removing the remaining portion of the fourth supporting material layer.
